(19) United States
(12) Patent Application Publication
(10) Pub. No.: US 2025/0107230 A1
(43) Pub. Date: Mar. 27, 2025

(54) SELECTIVE AND SELF-ALIGNED SOI THINNING FOR RF SWITCH APPLICATIONS

(71) Applicant: STMicroelectronics International N.V., Geneva (CH)

(72) Inventor: Franck JULIEN, La Penne sur Huveaune (FR)

(73) Assignee: STMicroelectronics International N.V., Geneva (CH)

(21) Appl. No.: 18/473,861

(22) Filed: Sep. 25, 2023

(51) Int. Cl. H01L 27/12; H01L 21/84

(52) U.S. Cl. CPC H10D 86/201; H10D 86/01

(57) ABSTRACT

A transistor device comprising a silicon-on-insulator (SOI) substrate having a plurality of polysilicon gates including a plurality of recessed gates and a plurality of non-recessed gates. The plurality of recessed gates being recessed in a top silicon layer of the SOI substrate and the plurality of non-recessed gates being on the top silicon layer. The plurality of recessed gates comprising an upper cap portion on a bottom buried portion that is in a recess of the SOI substrate. Methods of manufacturing the device are provided.

### BACKGROUND

### Technical Field

The present disclosure is directed to a device having a recessed gate in a silicon-on-insulator (SOI) substrate and methods of manufacturing the same.

### Description of the Related Art

Transistor devices, such as complementary metal-oxide semiconductor (CMOS) transistors, are used in an array of products such as 5G devices, mobile phones, antenna switches, and base station radio frequency (RF) switches. To improve performance of such devices while decreasing size, there are tradeoffs to consider. For example, in an RF switch there must be a compromise between Rₒₙ and C_{off} (RFVₘₐₓ), where Rₒₙ determines insertion or signal loss, C_{off} determines off-state isolation, and RFVₘₐₓ determines isolation breakdown. The goals is to optimize these values in order to improve performance of the device.

One trend to lower the C_{off} value is to use a thin substrate. However, this method increases cost and complexity of the device. Furthermore, too thin of a substrate can cause other issues such as higher Rₒₙ values due to an increase in signal loss during device performance. Another example is that when the substrate becomes too thin, it is then necessary to regrow the substrate in selected areas in order to keep the high dopant concentration areas necessary for low resistance. While the substrate being thin below the gate is beneficial, it may conversely be adverse in other areas of the device. One remedy is to regrow areas where the thin substrate is disadvantageous, however, this process of growing complicates the manufacturing process and increases costs. Currently, decreasing the thickness of the substrate is tied to complex and expensive costs of manufacturing.

Thus, it is advantageous to have a substrate with selective thickness throughout the substrate.

### BRIEF SUMMARY

The present disclosure is directed to a device comprising a silicon-on-insulator (SOI) substrate having first and second silicon layers, a first insulating layer between the first silicon layer and the second silicon layer, the first silicon layer having a first surface, and a recess in the first surface of the first silicon layer. The device further including a second insulating layer on the first surface of the first silicon layer and in the recess, and a first gate on the second insulating layer, the first gate having a first portion in the recess and a second portion on the first portion, the second portion being a different dimension than the first portion in a first direction. Methods of manufacturing the device are also disclosed.

The present disclosure is directed to a device having improved performance by optimizing Rₒₙ C_{off} (RFVₘₐₓ) values without degradation of other features and with intentional cost control methods for manufacturing. Some advantages of the present disclosure are self-alignment of the gate on the substrate and selective thinning of the substrate below the gate footprint rather than the entire substrate. Furthermore, the manufacturing methods and devices may apply to areas other than RF switches, such as SOI technology.

### BRIEF DESCRIPTION OF THE SEVERAL VIEWS OF THE DRAWINGS

In the drawings, identical reference numbers identify similar features or elements. The size and relative positions of features in the drawings are not necessarily drawn to scale, however the relationships between features are representative of relationships in a final product.

FIG. 1 is a plurality of recessed gates in a silicon-on-insulator (SOI) substrate and a plurality of gates on the SOI substrate, in accordance with some embodiments.

FIG. 2 is a cross-section view of a recessed gate from FIG. 3.

FIG. 3 is top view of a transistor device with a plurality of the recessed gates in FIG. 2.

FIGS. 4A and 4B are steps of a method of manufacturing a plurality of recessed gates.

FIGS. 5A-5E are steps of a method of manufacturing a plurality of recessed gates according to another embodiment.

FIG. 6 is a flow-chart of the steps of FIGS. 7A-7J.

FIGS. 7A-7J are steps of a method of manufacturing a plurality of gates according to another embodiment.

FIG. 8 is a flow-chart of the steps of FIGS. 9A-9H.

FIGS. 9A-9H are steps of a method of manufacturing a plurality of gates according to another embodiment.

### DETAILED DESCRIPTION

The present disclosure is directed to transistor structures in an RF or radio frequency device, such as a cell phone or antenna circuit. The transistor structures include controlled thinning of a silicon-on-insulator (SOI) substrate where RF transistors are formed. Another part of the same device may include other transistors that are not on a thinned SOI. The goal is improved Rₒₙ and C_{off} with a stable, or consistent RFVₘₐₓ or even better RFVₘₐₓ. This can be implemented in a small chip, such as 0.05 mm squared or 220 μm×220 μm.

The present disclosure is directed to local SOI thinning, at a transistor level. These are self-aligned gates in some embodiments. The present disclosure reduces or eliminates a re-epitaxial growth step of current techniques that thin the entire epitaxial layer. The present disclosure is directed to thinning the SOI only at the gate location or only within a small radius of the gate location.

FIG. 1 is a transistor device 101 formed on and in a silicon-on-insulator (SOI) substrate 110. The device 101 includes a plurality of recessed gates 230 in the SOI substrate 110 and spaced from a plurality of non-recessed gates 250 on or on top of the SOI substrate 110. An oxide or insulating layer 123 being between the plurality of gates 230, 250 and the SOI substrate 110. The plurality of recessed gates 230 being located in a first region 102 of the device 101. Whereas the plurality of non-recessed gates 250 are located in a second region 104 of the device 101. A shallow trench isolation 260 separates the first region 102 from the second region 104. In a final chip, these first and second regions may be spaced by other portions or circuits on the chip. They are illustrated as being separated by only the shallow trench isolation for simplicity.

Bottom and top are used for orientation and simplicity in understanding the Figures. Bottom and top are relative to the Figures as presented but may be reversed as positioned in a final product.

The SOI substrate 110 has a first silicon layer 112 with a bottom surface 114 opposite a top surface 119. The first silicon layer 112 being the bottom-most layer of the SOI substrate 110 with the bottom surface 114 being exposed and coupleable to another device or surface. The first silicon layer 112 may be bulk silicon or other suitable substrate material.

The SOI substrate 110 also has a buried oxide layer or region 200 on the first silicon layer 112. The buried oxide layer 200 has a bottom surface 202 contacting the top surface 119 of the first silicon layer 112. The top surface 119 of the first silicon layer 112 being substantially covered by the bottom surface 202 of the buried oxide layer 200. A top surface 207 of the buried oxide layer 200 that is opposite the bottom surface 202 is substantially covered by a second silicon layer 208. The buried oxide layer 200 may be silicon dioxide.

The second silicon layer 208 is part of the SOI substrate 110 and is the upper-most layer of the SOI substrate 110. A top surface 214 of the second silicon layer 208 being a top surface of the SOI substrate 110. Whereas a bottom surface 210 of the second silicon layer 208 contacts the top surface 207 of the buried oxide layer 200.

In some embodiments, the second silicon layer 208 has a thickness in a first direction greater than 10 nm. The first direction extends from top to bottom in FIG. 1. In some embodiments, the second silicon layer 208 thickness is between 60 and 300 nm. In specific embodiments, the second silicon layer 208 thickness is between 60 and 70 nm.

An oxide or insulating layer 123 covers or is otherwise on the top surface 214 of the second silicon layer 208. The insulating layer 123 contacts the top surface 214 of the second silicon layer 208. The insulating layer 123 extends between the recessed gate 230 and the substrate 110. More specifically, the insulating layer 123 covers the bottom surface 124 of the recess 120 in the substrate 110, including the sidewalls 122 of the recess 120. The insulating layer 123 is also between portions of a cap portion 240 that are on the top surface 214 of the second silicon layer 208. In some embodiments, the insulating layer 123 is absent.

A first, recessed gate 230 is in the recess 120 of the first region 102 of the device. The recessed gate 230 has a buried portion 232 in the recess 120 and a second, cap or upper portion 240 on the buried portion 232, with the upper portion 240 above the SOI substrate 110. While note only for RF devices, the first region 102 may be RF transistors and the second region 104 may be other types of transistors.

The insulating layer 123 extends in the second direction between the bottom surface 254 of the second gate 250 and the substrate 110. In some embodiments, the insulating layer 123 is on corners 216 of the second silicon layer 208.

The buried portion 232 includes a bottom surface 234 that is between or in an intermediate position between the surfaces 214, 210. The buried portion 232 extends in the first direction for a first dimension in the second silicon layer 208. In some embodiments, the first dimension of the buried portion 232 is less than half-way through the second silicon layer 208. The buried portion 232 includes lateral surfaces 235 adjacent to sidewalls 122 of the recess 120. In some embodiments, the bottom surface 234 of the buried portion 232 is curved. A second dimension of the buried portion 232 is between the lateral surfaces 235 in the second direction. The first dimension of the buried portion 232 is less than the second dimension of the buried portion 232. In some embodiments, the second dimension of the buried portion 232 is between 0.12 and 0.24 μm.

The upper cap portion 240 is wider and taller than the buried portion 232 of the recessed gate 230. The upper cap portion 240 has a top surface 242 opposite from the bottom surface 124 of the buried portion 232. The cap portion 240 extends outward, away from a center, in the second direction on the first surface 214 of the second silicon layer 208. The cap portion 240 overlaps the second silicon layer 208. The gate 230 is T-shaped in some embodiments.

The cap portion 240 has a first dimension in the first direction that is greater than the first dimension of the buried portion 232. The cap portion 240 has a second dimension in the second direction that is greater than the second dimension of the buried portion 232.

The recessed gate 230 has indentations delimited or defined by the lateral surfaces 235 of the buried portion 232 and outer edges of the cap portion 240. The recessed gate 230 has at least two indentations that are opposite each other.

The insulating layer 123 may have a constant thickness in the first direction. In some embodiments, the thickness of the insulating layer 123 is from 1 to 15 nm. In specific embodiments, the thickness of the insulating layer 123 may be about 5 nm. The insulating layer 123 may be an oxide layer of silicon dioxide or silicon oxynitride (SiON). The top surface 264 of the shallow trench isolation 260 may be from the insulating layer 123. In some embodiments, the top surface 264 of the shallow trench isolation 260 is covered by the insulating layer 123. The first silicon layer 112 has a first dimension along the first direction that extends from the bottom surface 114 to the top surface 119. The buried oxide layer 200 has a second dimension along the first direction from the bottom surface 202 to the top surface 207. The second silicon layer 208 has a third dimension from the bottom surface 210 to the top surface 214. The third dimension of the second silicon layer 208 may be less than the first dimension. The third dimension of the second silicon layer 208 may be less than the second dimension.

The three layers of the SOI substrate 110, including the first silicon layer 112, the buried oxide layer 200, and the second silicon layer 208, each have substantially similar dimensions between respective lateral surfaces. The lateral surfaces of the three layers being substantially coplanar with each other.

A shallow trench isolation 260 extends from the buried oxide layer 200 through the second silicon layer 208. In some embodiments, the shallow trench isolation 260 extends past the top surface 214 of the second silicon layer 208. The shallow trench isolation 260 may have tapered sidewalls 262 and a first dimension, in a second direction transverse to the first direction, between the tapered sidewalls 262. The first dimension may be nearer to the top surface 207 of the buried oxide layer 200 than the top surface 214 of the second silicon layer 208. The shallow trench isolation 260 has a second dimension, in the second direction, between the tapered sidewalls 262. The second dimension of the shallow trench isolation 260 being greater than the first dimension. The second dimension being at a top surface 264 of the shallow trench isolation 260 and extending above the top surface 214 of the second silicon layer 208, in some embodiments.

The shallow trench isolation 260 may separate a first region 102 and a second region 104 of the device 100. The first region 102 has a recess 120 in the second silicon layer 208. The shallow trench isolation 260 may be adjacent to the recess 120. The SOI substrate 110 may include a plurality of recesses 120 spaced from each other and located in the first region 102. In some embodiments, the shallow trench isolation 260 is absent. In other embodiments, there are a plurality of shallow trench isolations.

The recess 120 has sidewalls 122 and an interior, bottom surface 124 that is between the top surface 214 of the second silicon layer 208 and the top surface 207 of the buried oxide layer 200. In some embodiments, the bottom surface 124 is nearer the top surface 214 of the second silicon layer 208 than the top surface 207 of the buried oxide layer 200. The sidewalls 122 are opposite to each other and extend from the bottom surface 124 of the recess 120 to the top surface 214 of the second silicon layer 208. In some embodiments, the recess 120 is curved.

In some embodiments, the recess sidewalls 122 delimit corners 216 of the second silicon layer 208. The recess 120 has a first dimension in the first direction from the bottom surface 124 of the recess 120 to the top surface 214 of the second silicon layer 208. The recess 120 has a second dimension in the second direction of the bottom surface 124 between the sidewalls 122. The first dimension is less than the second dimension, in some embodiments. The first dimension of the recess 120 may be between 5 to 50 nm. In some embodiments, the first dimension of the recess 120 is between 10 and 30 nm. The second silicon layer 208 may have a thickness in the first direction under the recess 120 that is between 50 and 130 nm. In some embodiments, the thickness of the second silicon layer 208 is 60 nm.

In some embodiments, the corners 216 of the second silicon layer 208 are positioned below the cap portion 240 and above the bottom surface 234 of the buried portion 232.

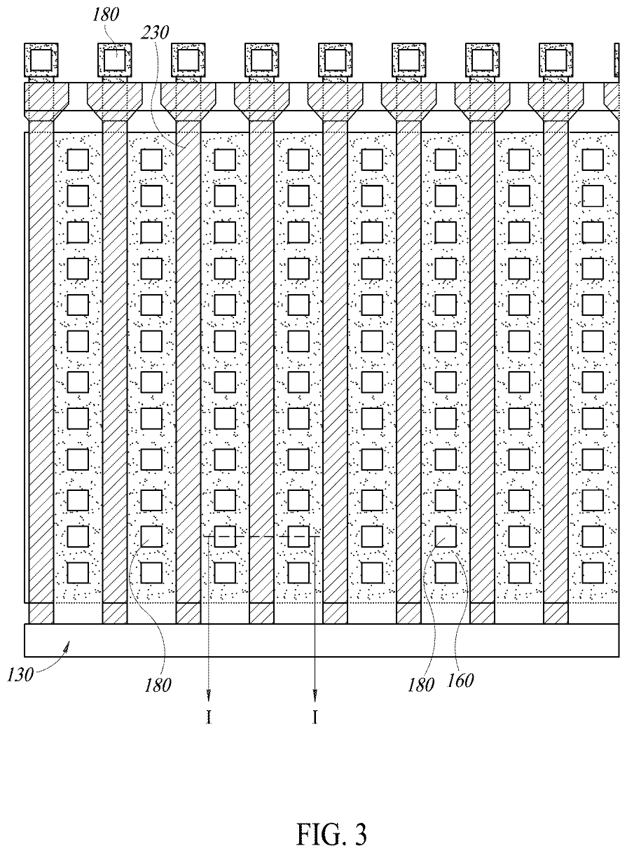

The recessed gate 230 may be a polysilicon gate or other suitable conductive material. In some embodiments, the recessed gate 230 may be T-shaped. The device 101 may include a plurality of recessed gates 230, with the recessed gates 230 being spaced from each other. An end of the cap portion 240 of the recessed gate 230 may face the end of the cap portion of another recessed gate that are arranged in an array, such as that of FIG. 3.

A plurality of second gates 250 are located in the second region 104 of the device 100, spaced from the plurality of first gates 230. The second gate 250 is on the top surface 214 of the second silicon layer 208. The second gate 250 has a top surface 252, a bottom surface 254, and lateral surfaces 256 between the top surface 252 and the bottom surface 254. The bottom surface 254 is on the top surface 214 of the second silicon layer 208. A first dimension of the second gate 250 being between the top surface 252 and the bottom surface 254 in the first direction. A second dimension of the second gate 250 being between the lateral surfaces 256 in the second direction. In some embodiments, the first dimension of the second gate 250 is substantially similar to the second dimension of the cap portion 240 of the recessed gate 230 and the second dimension of the second gate 250 is substantially similar to the first dimension of the cap portion 240.

The second gate 250 may also be a polysilicon gate. The second gates 250 may be the same material as the first gates 230. In some embodiments, the second gate 250 is substantially rectangular-shaped. The second gate 250 may be adjacent and spaced from the shallow trench isolation 260. The lateral surface 256 of the second gate 250 may face the lateral surface of another second gate.

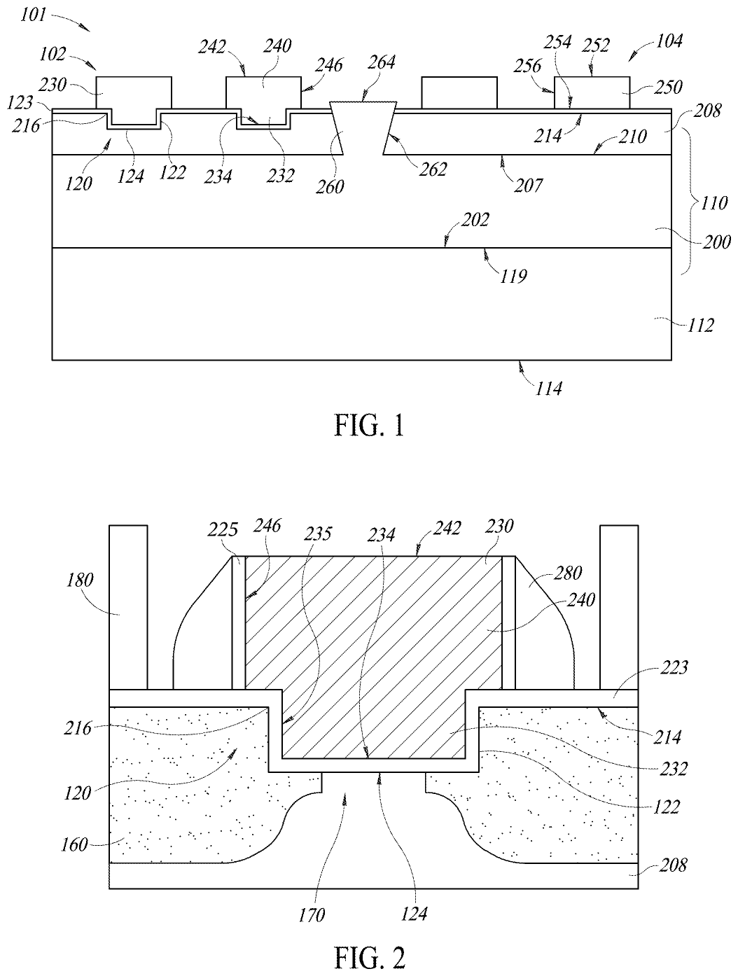

FIG. 2 is a cross-section view along line I-I of FIG. 3, which is a top-down view of an array of transistors. Features that are consistent with those in FIG. 1 may have the same reference numerals. The transistors comprise a plurality of recessed gates 230 in an SOI substrate 110 with the recessed gates 230 being spaced from each other along a first direction (horizontal in FIG. 3). A gate contact 130 couples each first end of each of the recessed gates 230 along the first direction. The gate contact 130 extends transverse to the extension of each of the recessed gates 230. Second ends of the recessed gates 230, opposite the first ends, are coupled to contacts 180. Additional contacts 180 are on the SOI substrate 110 and between adjacent recessed gates 230, see FIG. 3. In particular, the contacts 180 are spaced from each other on an active region 160 of the SOI substrate 110.

Doped regions in a second silicon layer 208 of the SOI substrate 110 comprise the active region 160. The doped regions are formed in and around each recess 120 in the second silicon layer 208 and a top surface 214 of the second silicon layer 208. In some embodiments, the doped regions do not reach a bottom surface 210 of the second silicon layer 208. In other embodiments, the doped regions reach the bottom surface 210 of the second silicon layer 208. These doped regions form the source and drain of the transistor and shape or otherwise create the boundary of a channel region under the gate 230.

The doped regions include N− doped regions and N+ doped regions, with the N− doped regions being nearer to the recess 120 than the N+ doped regions. Whereas the N+ doped regions are nearer to the bottom surface 210 than the top surface 214 of the second silicon layer 208. The N+ doped regions extending further into the second silicon layer 208 in the first direction, towards the bottom surface 210, than the N− doped regions below the recess 120.

The doped regions extend up to corners 216 of the second silicon layer 208, where sidewalls 122 of the recess 120 meet the top surface 214 comprising the corners 216. The doped regions extending in the first direction adjacent the sidewalls 122. The N− doped regions extend to the top surface 214.

Portions of opposite N− doped regions extend towards each other below the recess 120, but do not contact each other. A channel 170 is formed below the recess 120 between opposite N− doped regions and a portion of the second silicon layer 208 below the recess 120 that does not have any doped regions. The channel 170 is below the recessed gate 230 that is in the recess 120, in particular a buried portion 232 of the recessed gate 230. In some embodiments, the N− doped regions below the recess 120 and the recessed gate 230 extend between about 10-20 nm in the second direction.

An insulating or oxide layer 223 extends on the active region 160 and is in the recess 120. The insulating layer 223 covers the top surface 214 of the second silicon layer 208 including the sidewalls 122 and bottom surface 124 of the recess 120. The insulating layer 223 covering corners 216 of the second silicon layer 208. Another insulating layer 225, which can be oxide, extends transverse to the top surface 214 along lateral surfaces 246 of the recessed gate 230. Top surfaces of the insulating layer 225 being coplanar with the top surface 242 of the recessed gate 230. The insulating layer 223 are between the recessed gate 230 and a plurality of spacers 280. The spacers 280 are not shown in the top-down view of FIG. 3 for simplicity purposes.

The plurality of spacers 280 are adjacent to the lateral surfaces 246 of the cap portion 240 of the recessed gate 230. The insulating layer 223 extends between each spacer 280 and the cap portion 240 of the recessed gate 230. The insulating layer 223 also extends between a bottom surface of the spacer and the top surface 214 of the second silicon layer 208. The insulating layer 223 has a substantially similar thickness throughout. In some embodiments, the insulating layer 223 substantially surrounds the recessed gate 230 except for the top surface 242.

The spacers 280 have an outer curved surface that extends down to the insulating layer 223 on the second silicon layer 208. The spacers 280 taper towards the top surface 242 of the cap portion 240. The spacer 280 has a first end on the second silicon layer 208 and a first dimension in the second direction. The spacer 280 has a second end opposite the first end and a second dimension in the second direction. The second dimension of the spacer 280 being less than the first dimension of the spacer. The second end of the spacer 280 being nearer to the top surface 242 of the cap portion 240 than the first end. In some embodiments, the first dimension of the spacer is between 20 and 40 nm.

A plurality of contacts 180 are spaced from the spacers 280. In particular, a contact is adjacent and spaced from a spacer 280. The contacts 180 are illustrated on the insulating layer 223 on the top surface 214 of the second silicon layer 208, however, in a final product the contacts may be in direct contact or in electrical contact through conductive layers with the doped regions. The contacts 180 extend in the first direction past the top surface 242 of the recessed gate 230.

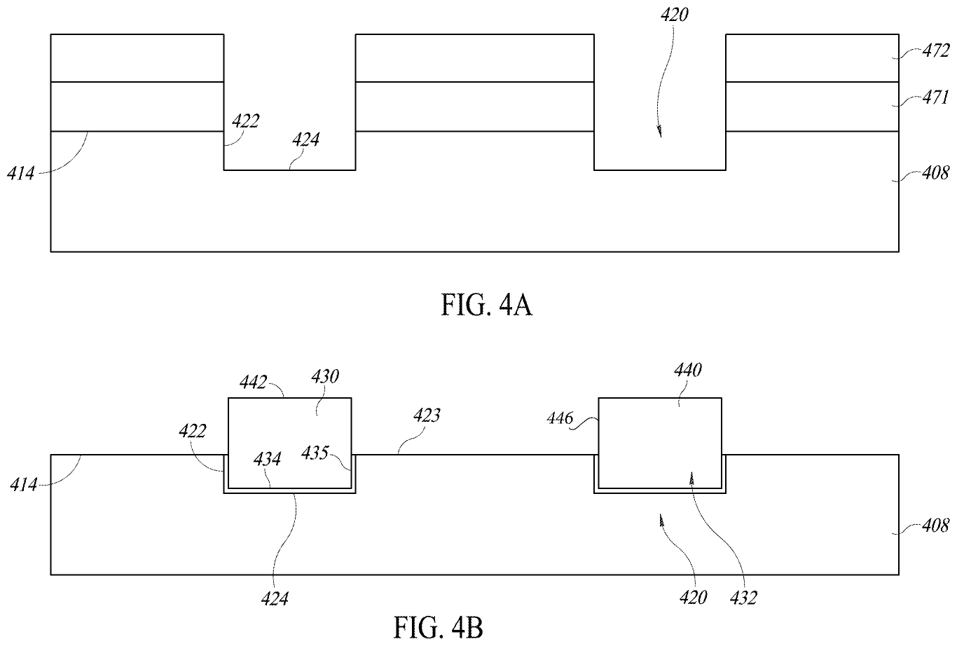

FIGS. 4A and 4B are a method of manufacturing a plurality of recessed gates 430 according to another embodiment. An SOI substrate is provided having a top silicon layer 408. The other layers of the SOI substrate including a buried oxide region below the top silicon layer 408 and a bottom silicon layer below the buried oxide region are not shown for simplicity. In some embodiments, the second silicon layer 408 has a thickness in the first direction of about 70 nm.

A nitride layer or masking region 471 substantially covers a top surface 414 of the top silicon layer 408. The nitride layer 471 is silicon nitride, or other suitable material. A photoresist layer or patterning region 472 patterns a top surface of the nitride layer 471. Then, a plurality of recesses 420 are formed by etching the second silicon layer 408 through the nitride layer 471. Each formed recess 420 is spaced from each other. The recesses are formed in the top surface 414 of the second silicon layer 408. Etching exposes the top surface 414 of the second silicon layer 408. Only the gate recess area 420 is etched in the SOI.

Each recess 420 has a bottom surface 424 in the second silicon layer 408 and lateral sidewalls 422 extending from the bottom surface 424 to the top surface 414 of the second silicon layer 408. The sidewalls 422 are transverse to the top surface 414 and the bottom surface 424.

Then, an insulating layer 423 is formed in the recesses 420 coating the bottom surfaces 424 and sidewalls 422. The insulating layer 423 is continuous on along the sidewalls 422 of the recesses 420 and on the exposed top surface 414 of the second silicon layer 408, e.g., the bottom surface 424 of the recess 420. The insulating layer 423 has top surfaces that are coplanar with the top surface 414 of the second silicon layer 408. The top surfaces of the insulating layer 423 are adjacent the sidewalls 422 of the recesses 420. In other embodiments, the insulating layer 423 extends past the top surface 414 of the second silicon layer 408 and along lateral surfaces of the nitride layer 471. In other embodiments, the insulating layer 423 may be omitted.

Then, the recessed gates 430 are formed. In this embodiment, the recessed gates 430 are formed on the insulating layer 423. Forming the recessed gates 430 includes forming conductive gate material in the recesses 420. The conductive gate material is formed using an inverse of the recessed gates 430.

The formed recessed gate 430 includes the upper portion 440 integral with the buried portion 432. The upper portion 440 is centrally aligned with the buried portion 432. The upper portion 440 extends past the top surface 414 of the second silicon layer 208, while the buried portion 432 extends below the top surface 414. The buried portion 432 is in the recessed 420.

In this embodiment, the buried portion 432 does not extend onto the top surface 414 of the second silicon layer 408. In this embodiment, lateral surfaces 446 of the upper portion 440 and lateral surfaces 435 of the buried portion 432 are coplanar. In this embodiment, the first and second dimensions of the recessed gate 430 are substantially similar and the upper portion 440 does not extend on the top surface 414 of the second silicon layer 408. In particular, the first and second dimensions are between and include 0.065 and 0.24 μm.

In some embodiments, the first dimension of the recessed gate 430 is less than the second dimension of the recessed gate 430 and the lateral surfaces 446, 435 of the upper portion 440 and the buried portion 432 are not coplanar. In some embodiments, portions of the insulating layer 423 are present along the lateral surfaces 446 of the upper portion 440 of the recessed gate 430.

After the insulating layer 423 is formed, the photoresist layer 472 and nitride layer 471 are removed. While FIGS. 4A-4B are an elegant solution, there is risk that the may be gaps between the sidewalls of the recess and the conductive material of the gate.

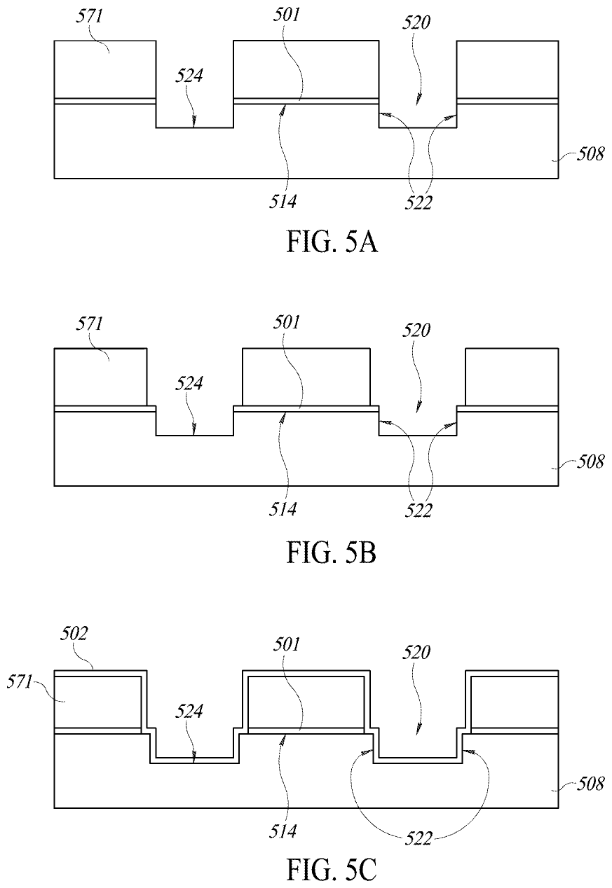

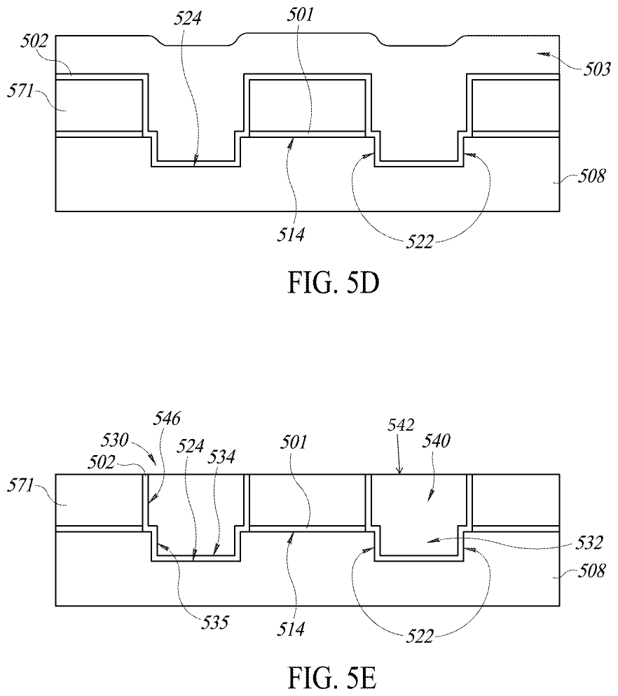

FIGS. 5A-5E are steps of a method of making a plurality of recessed gates 530 according to another embodiment, with each recessed gate 530 having a cap portion 540 that extends onto a surface of the substrate and reduces a risk of a gap in the recess. An SOI substrate is provided having a top silicon layer 508 on a buried oxide layer. Below the buried oxide layer is a bottom silicon layer, both layers are not shown for simplicity. A top surface 514 of top silicon layer 508 is a top surface of the SOI substrate. Not shown for simplicity, at least one or a plurality of shallow trench isolations extending from the buried oxide layer past the top surface 514 are formed in the SOI substrate. The shallow trench isolation separates these transistors, which may be RF transistors, from other types of transistors in the final integrated circuit or chip.

A first insulating layer 501 is on and substantially covers the top surface 514. The first insulating layer 501 comprises silicon dioxide or other suitable insulating material. The first insulating layer 501 has a substantially uniform thickness throughout.

On the first insulating layer 501 is a nitride layer 571 that substantially covers the first insulating layer 501 so that the first insulating layer 501 is sandwiched between the top surface 514 and the nitride layer 571. The nitride layer 571 comprises silicon nitride or other suitable material. The nitride layer 571 has a substantially uniform thickness throughout. The nitride layer 571 has a thickness in the first direction that is significantly greater than a thickness in the first direction of the first insulating layer 501. In some embodiments, the first insulating layer 501 is absent.

The nitride layer 571 is patterned using a mask of an inverse of the recessed gates 530.

Then, in FIG. 5A, a plurality of recesses 520 are formed in the top surface 514, with each recess 520 being spaced from each other. Forming the recesses 520 includes etching, using the mask, through the nitride layer 571 and the first insulating layer 501. Portions of the top silicon layer 508 are also etched, but etching stops in the top silicon layer 508, at an intermediate location. In some embodiments, etching in the first direction stops midway or before midway in the top silicon layer 508.

Etching exposes portions of the top silicon layer 508 and lateral surfaces of the nitride layer 571 and the first insulating layer 501. The exposed lateral surfaces of the nitride layer 571 and the first insulating layer 501 are transverse to the top surface 514 of the second silicon layer 208 and are coplanar with lateral exposed surfaces of the top silicon layer 508. The lateral exposed surfaces of the top silicon layer 508 delimit sidewalls 522 of the recesses 520.

Each of the formed recesses 520 has a bottom surface 524 delimited by the top silicon layer 508. The bottom surface 524 is transverse to the sidewalls 522. The bottom surface 524 is located in the top silicon layer 508 nearer to the top surface 514 than an opposite bottom surface of the top silicon layer 508. Each recess 520 has a first dimension between the sidewalls 522. A second dimension between each recess 520 is greater than the first dimension of the recess 520. In other embodiments, the second dimension is substantially similar or less than the first dimension.

After etching, the top silicon layer 508 has a first thickness from the top surface 514 to the bottom surface and a second thickness from the bottom surface 524 of the recess to the bottom surface of the top silicon layer 508. The first thickness is greater than the second thickness. A column or stack comprising portions of the nitride layer 571, the first insulating layer 501, and the top silicon layer 508 is formed between adjacent recesses 520.

Then, in FIG. 5B, the nitride layer 571 is etched at lateral surfaces. Etching reduces a thickness of the nitride layer 571 between the lateral surfaces. In some embodiments, etching is carried out by nitride pull-back.

Etching the nitride layer 571 exposes top surfaces of portions of the first insulating layer 501. Lateral surfaces of the first insulating layer 501 are no longer coplanar with lateral surfaces of the nitride layer 571. Instead, lateral surfaces of the first insulating layer 501 remain coplanar with the sidewalls 522 of the recesses 520. The exposed portions of the first insulating layer 501 form a step-like feature or corner between the nitride layer 571 and the sidewalls 522. In some embodiments, etching the nitride layer 571 is optional.

In FIG. 5C a second insulating layer 502 is formed on the top silicon layer 508. The second insulating layer 502 continuously covers the nitride layer 571, including top and lateral surfaces of the nitride layer 571. Exposed portions of the top silicon layer 508, including the sidewalls 522 and the bottom surfaces 524 of the recesses 520 are coated with the second insulating layer 502. The second insulating layer 502 contacts the first insulating layer 501 and has a uniform thickness throughout. The second insulating layer 502 is of the same material as the first insulating layer 501 or other suitable insulating material.

Then, gate polysilicon material 503 is deposited in the recesses 520 in FIG. 5D. The second insulating layer 502 being between the gate polysilicon material 503 and the nitride layer 571. In some embodiments, the gate polysilicon material 503 completely fills the recesses 520. In some embodiments, the gate polysilicon material 503 overfills the recesses 520 and covers the second insulating layer 502 on the top surface of the nitride layer 571.

The recessed gates 530 in the recesses 520 are defined in FIG. 5E. Chemical mechanical polishing, or another suitable method, is carried out to remove top portions of the gate polysilicon material 503. Then, phosphoric acid (H₃PO₄), hydrofluoric acid (HF), or a combination thereof, may be used to remove portions of the second insulating layer 502. Removal exposes top surfaces of the nitride layer 571 that are coplanar with exposed top surfaces 542 of the recessed gates 530. Removal also exposes top surfaces of the second insulating layer 502 that are coplanar with the top surfaces of 542 of the recessed gates 530.

The formed recessed gates 530 comprise the cap portion 540 on a buried portion 532 in the recess 520. The second insulating layer 502 is continuous and integral with the first insulating layer 501. The second insulating layer 502 being between the recessed gates 530 and the top silicon layer 508. The first and second insulating layers 501, 502 being between the recessed gates 530 and the nitride layer 571.

Afterwards, the nitride layer 571 is removed, which is not shown for simplicity. Subsequent steps may be carried out to produce the recessed gate 230 of FIG. 2. In some embodiments, steps of forming lightly doped drain regions and forming spacers 280 are carried out.

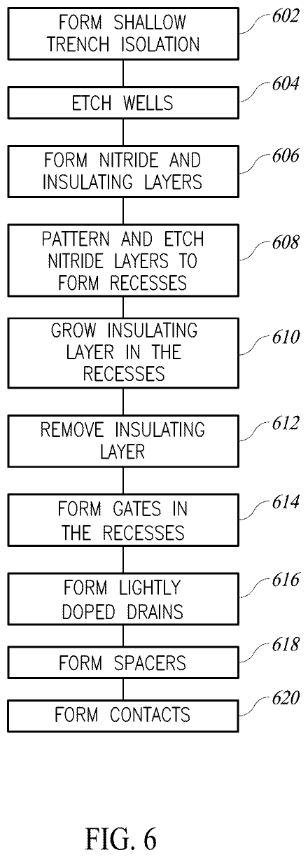

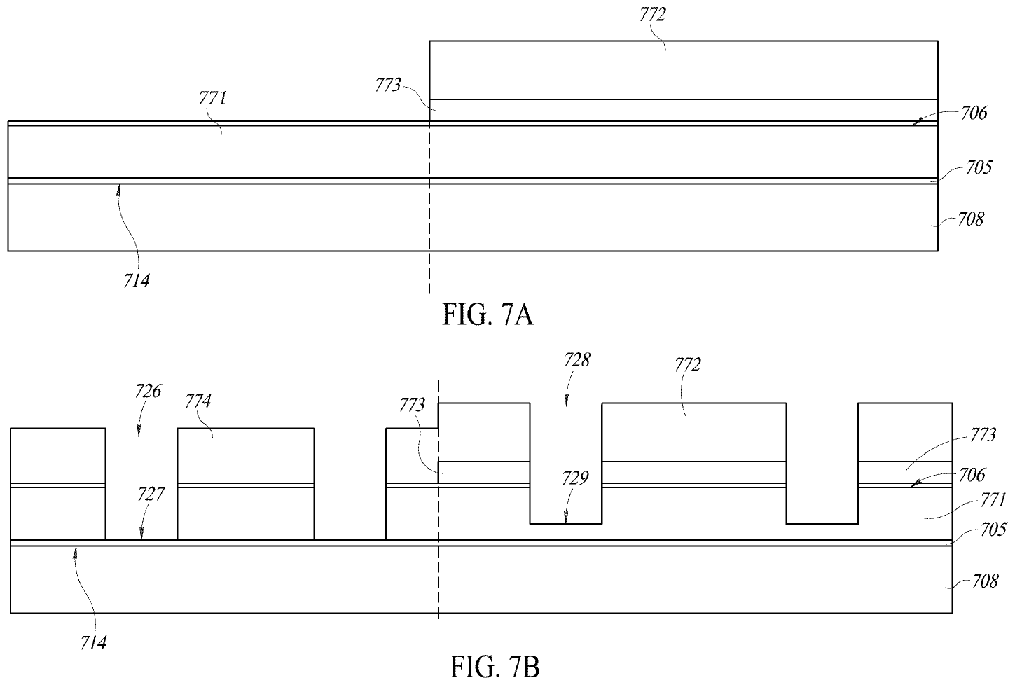

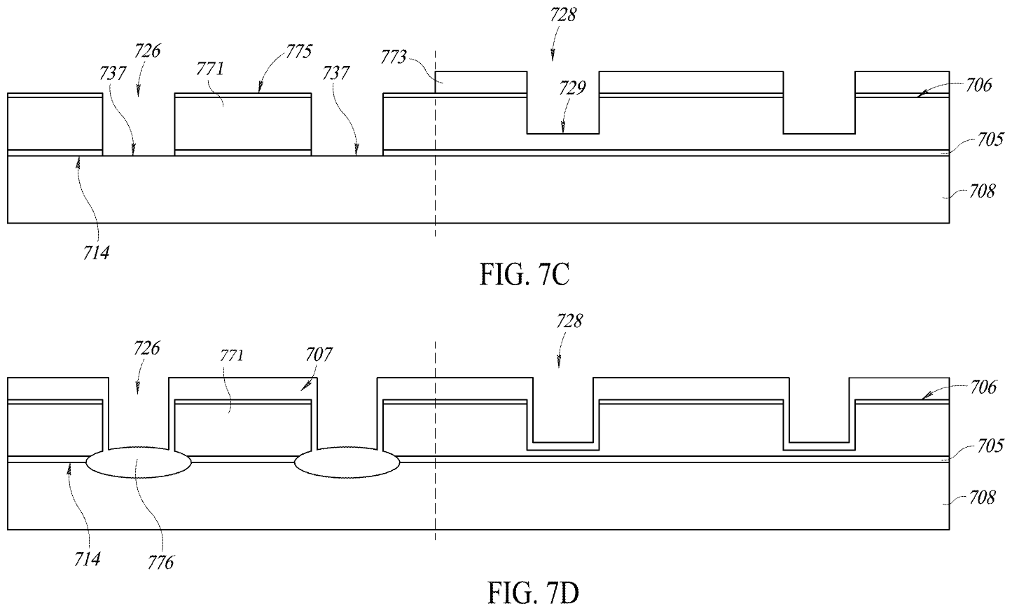

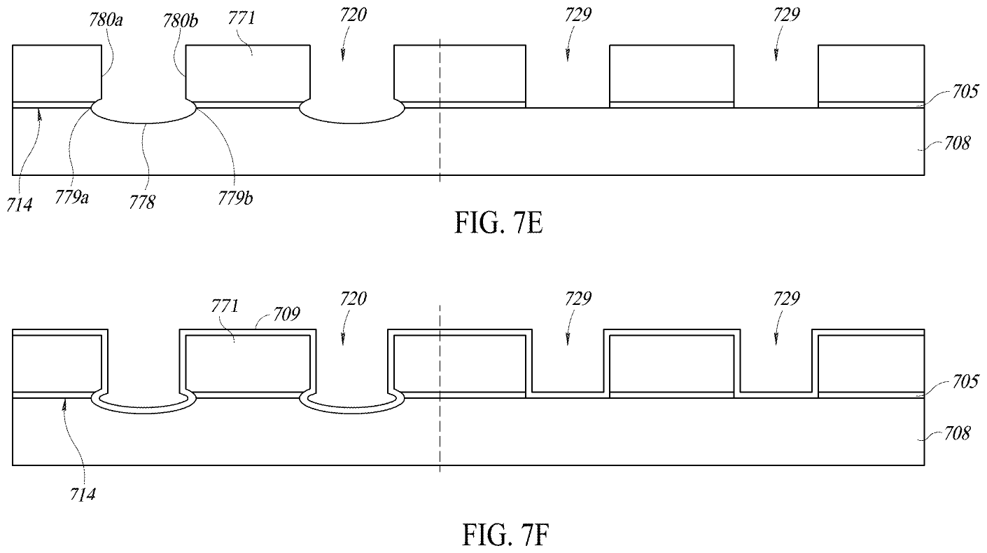

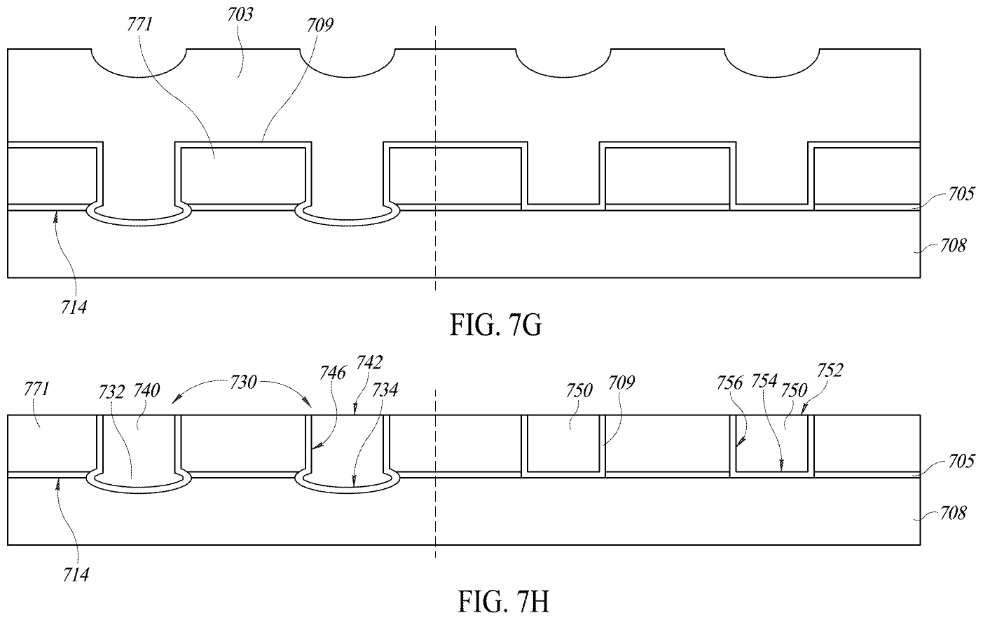

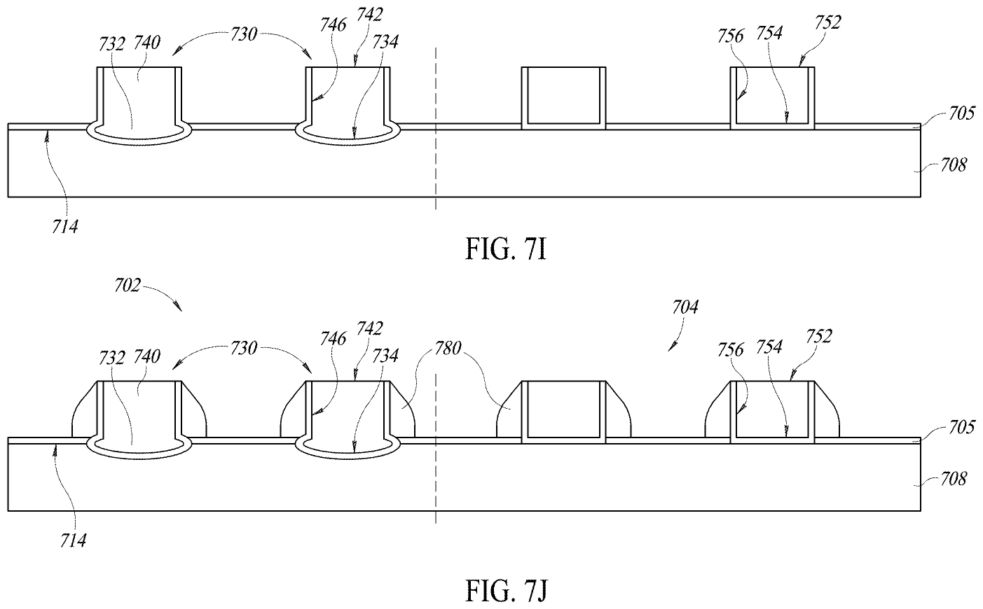

FIG. 6 and FIGS. 7A-7J area flow chart of steps of a method of manufacturing and a device that includes a plurality of gates according to another embodiment of the present disclosure. The plurality of gates includes a plurality of recessed gates 730 and a plurality of non-recessed gates 750, see FIG. 7H. The plurality of gates are formed on a silicon on insulator (SOI) substrate, which includes a top silicon layer 708 that is on a buried oxide layer. The buried oxide layer is on a bottom silicon layer. Both the buried oxide layer and the bottom silicon layer are not shown for simplicity. A first insulating layer 705 is formed on a top surface 714 of the top silicon layer 708. The first insulating layer 705 substantially covers the top surface 714 and is made of silicon dioxide or other suitable material. The first insulating layer 705 has a uniform thickness throughout. The top silicon layer 708 may have a thickness from 60 to 300 nm from a bottom surface to the first insulating layer 705.

At step 602 of the method, shallow trench isolation structures are formed in the SOI substrate, which is not shown in FIGS. 7A-7J for simplicity. The shallow trench isolation may have similar features as detailed in FIG. 1. The shallow trench isolation structures are formed to separate the plurality of recessed gates 730 from other gates and circuit structures in a final device.

Then, at step 604, wells are etched including doped regions in the SOI substrate according to the final transistor design. This step is not shown in FIGS. 7A-7J for drawing clarity.

Next, at step 606, nitride layers 771, 773 and insulating layers 705, 706 are formed on the SOI substrate, see FIG. 7A. In some embodiments, the first insulating layer 705 completely covers the top surface 714. In other embodiments, the insulating layer 705 partially covers the top surface 714. In some embodiments, the first insulating layer 705 is absent. Covering and on the first insulating layer 705 is a first nitride layer 771. The first nitride layer 771 is silicon nitride or other suitable material. The first nitride layer 771 has a uniform thickness throughout.

In some embodiments, the first nitride layer 771 completely covers or partially covers a top surface of the first insulating layer 705. Where there is no insulating layer 705, the first nitride layer 771 is on and covers, partially or completely, the top surface 714 of the top silicon layer 708.

A second insulating layer 706 is on the first nitride layer 771. The second insulating layer 706 may be made of the same material as the first insulating layer 705, or other suitable insulating material. The second insulating layer 706 entirely covers a top surface of the first nitride layer 771. The second insulating layer 706 has a uniform thickness throughout. The second insulating layer 706 is thinner than the nitride layer 771. The first nitride layer 771 may have a thickness of 120 nm from the first insulating layer 705 to the second insulating layer 706.

A second nitride layer 773 is formed or deposited on the second insulating layer 706. The second nitride layer 773 is patterned and shaped with a photoresist layer 772 to not completely cover a top surface of the second insulating layer 706. Rather, only a portion of the second insulating layer 706 is covered by the second nitride layer 773 so that a region of the second insulating layer 706 is exposed, see FIG. 7A. The second nitride layer 773 may be of the same material as the first nitride layer 771, or other suitable material. The second nitride layer 773 has a smaller thickness from a top surface to the second insulating layer 706 than a thickness of the first nitride layer 771 that is between the first and second insulating layers 705, 706. In some embodiments, the thickness of the second nitride layer 773 is greater than or equal to the thickness of the first nitride layer 771. The second nitride layer 773 may have a thickness between 20-50 nm from the second insulating layer 706 to a first photoresist layer 772.

The dashed line is for illustrative purposes only and divides the device into an RF switch area on the left side and a digital area on the right side.

Then, at step 608, the nitride layers 771, 773 are patterned and etched using a second photoresist layer 774 and masks to form a plurality of openings 726. The first photoresist layer 728 is used to create the plurality of openings 728 in the digital side of the device. This corresponds to FIG. 7B, where the etching of the first and second photos resist layers 772 and 774 is performed at a same time such that a depth or time of the etch for forming the plurality of openings 726 and 728.

Then, a plurality of openings 726, 728 including a plurality of first openings 726 and a plurality of second openings 728. The plurality of first openings 726 are formed by etching through the second insulating layer 706 and the first nitride layer 771 to expose the first insulating layer 705. Each first opening 726 has a bottom surface 727 delimited by the first insulating layer 705 that is now exposed by the etching step and sidewalls of the nitride layer 771 and the second insulating layer 706.

The plurality of second openings 728 are formed by etching through the second nitride layer 773, the second insulating layer 706, and into the first nitride layer 771. However, etching the second openings 728 stops in the first nitride layer 771 at an intermediate surface 729. The surface 729 is spaced from the first insulating layer 705 by a distance that is greater than zero. Each second recess 728 has a bottom surface 729 delimited by the first nitride layer 771.

Etching the plurality of first and second openings 726, 728 exposes lateral surfaces of the photoresist layers 772, 774, the first and the second insulating layers 705, 706, and the first and the second nitride layers 771, 773. At least one of the first openings 726 is adjacent and spaced from one of the second openings 728. The first and second openings 726, 728 separate portions of the photoresist layers 772, 774, the second insulating layer 706, and the first and second nitride layers 771, 773 so each are no longer continuous.

In FIG. 7C, the photoresist layers 772, 774 areas removed exposing the second nitride layer 773 and a top surface 775. Portions of the second insulating layer 706 are now also exposed where the second nitride layer 773 is not present. The exposed portions of the first insulating layer 705, that delimit the bottom surfaces 727 of the first openings 726, are removed, for example, by etching or other suitable method. Afterwards, a bottom surface 737 of the opening 726 is the top surface of the silicon layer 708.

In embodiments where the second insulating layer 706 is not present, the entirety of the top surface of the first nitride layer 771 is now exposed.

At step 610, a third insulating layer 707 is formed on the SOI substrate and in the openings 726, 728, see FIG. 7D. The third insulating layer 707 covers the second insulating layer 706 and coats sidewalls of the first and second opening 726, 728, which include lateral surfaces of the first nitride layer 771 and lateral surfaces of the first and second insulating layers 705, 706. Bottom surfaces 737, 729 of the first and second opening 726, 728 also include the third insulating layer 707. However, since first nitride layer 771 protects the second openings 728, the third insulating layer 707 is on the first nitride layer 771 at the bottom surfaces 729 of the second openings 728. The third insulating layer 707 may be made of the same material as the first or second insulating layers 705, 706 or other suitable insulating material.

Forming the third insulating layer 707 includes growing the third insulating layer 707. In particular, the third insulating layer 707 is grown in the SOI substrate at the top surface 714 of the top silicon layer 708. Growing the third insulating layer 707 forms convex edges at the bottom surface 737 of the opening 726. The third insulating layer 707 is grown and expands in all directions at the bottom surface 737 of the opening 726. The third insulating layer 707 protrudes into the top silicon layer 708 forming a convex edge below the top surface 714. The third insulating layer 707 located on the bottom surfaces 729 of the second opening 728 are not grown in this manner as the bottom surface is in the nitride layer 771.

A curved mass 776 is formed at the boundary between the third insulating layer and the silicon layer. The first and second openings now have different shapes from each other.

At step 612, the third insulating layer 707 is removed, which is shown in FIG. 7E. This step includes forming or otherwise exposing a plurality of first and second openings 720, 729. Removing the second and the third insulating layers 706, 707 forms the shape and size of the plurality of first and second openings 720, 729. In particular, removing the third insulating layer 707 removes portions of the top silicon layer 708 where the third insulating layer 707 was grown at the bottom surfaces 737 of the opening 726. The curved mass 776 is removed, leaving a curved bottom 778. Edges 779a, 779b of the curved bottom 778, the outermost aspects of this opening 720 are wider than sidewalls 780a, 780b. The sidewalls are substantially vertical, or linear, while the bottom has a curved or rounded shape.

Said differently, the first openings 720 having rounded bottom or lowered surfaces delimited by the top silicon layer 708, where the rounded bottom surfaces are in the top silicon layer 708. While the second openings 729 have flat bottom surfaces delimited by the top silicon layer 708. The second openings 729 do not substantially extend into the top silicon layer 708, whereas the first openings 720 do extend into the top silicon layer 708.

Both the first and second openings 720, 729 have substantially straight sidewalls delimited by the first nitride layer 771. Lateral surfaces of the first insulating layer 705 delimit the substantially straight sidewalls of the second openings 729. Whereas lateral surfaces of the first insulating layer 705 delimit curved sidewalls of the first openings 730, where the curved sidewalls are below or underneath the substantially straight sidewalls. Bottom surfaces of the first nitride layer 771 also delimit the curved sidewalls of the first openings 730.

Removing the second and the third insulating layers 706, 707 exposes the first nitride layer 771. However, removing the second and third insulating layer 706, 707 does not remove portions of the first nitride layer 771. In particular, the top surfaces and the lateral surfaces of the first nitride layer 771 are exposed. Additionally, in the first openings 720, bottom surfaces of the first nitride layer 771 are also exposed. Lateral surfaces of the first insulating layer 705 are also exposed in both the first and the second openings 720, 729.

Then, a fourth insulating layer 709 is formed on the SOI substrate in FIG. 7F. The fourth insulating layer 709 being on the first nitride layer 771 including the lateral surfaces of the first nitride layer 771. The openings 720, 729, including sidewalls and bottom surfaces are coated and covered by the fourth insulation layer 709. The fourth insulating layer 709 having a uniform thickness throughout and being of the same material as the first insulating layer 705, or other suitable insulating material. The first insulating layer 705 being integrated with the fourth insulating layer 709.

The plurality of gates 730, 750 are then formed in the openings 720, 729 at step 614 by forming a conductive layer 703 in each of the openings and on the fourth insulating layer 709. This includes a chemical mechanical polish to remove excess portions of the conductive layer 703 so that a top surface of each gate 730,750 are substantially coplanar. Then, phosphoric acid (H₃PO₄), hydrofluoric acid (HF), or a combination thereof, may be used to remove portions of the second insulating layer.

In some embodiments, the silicon dioxide or silicon nitride deposition is followed by the silicon dioxide or silicon nitride etch. A gate inverse mask (gate last) step follows the silicon dioxide or silicon nitride etch. Then further silicon dioxide or silicon nitride removal occurs. A gate oxide and poly formation follows. Then a CMP and phosphoric acid (H₃PO₄) step may follow. In FIG. 7G, the conductive layer 703 may be a gate polysilicon material 703 is deposited on the SOI substrate. The gate polysilicon material 703 overfills the first and second openings 720, 729. The fourth insulating layer 709, including a top surface, is covered by the gate polysilicon material 703. In particular, the gate polysilicon material 703 extends to coat the bottom surfaces of the openings 720, 729.

The CMP step removes excess gate polysilicon material 703 The CMP step exposes top surfaces of the fourth insulating layer 709 and the top surfaces of the first nitride layer 771. The top surfaces of the first nitride layer 771 and the top surfaces of the fourth insulating layer 709 being coplanar with top surfaces of the gates 730, 750.

In some embodiments, portions of the first nitride layer 771 are not removed during the step of forming the gates 730, 750. In some embodiments, portions of the fourth insulating layer 709 are not removed during the step of forming the gates 730, 750.

In other embodiments, no non-recessed gates 750 are formed. In some embodiments, one or at least one recessed gate 730 is formed. In some embodiments, one or at least one non-recessed gate 750 is formed. The first and fourth insulating layer 705, 709 are integral with each other. The fourth insulating layer 709 protruding transversely, along sidewalls of the gates 730, 750, to the first insulating layer 705.

The recessed gates 730 are formed having a bottom buried portion 732 in the top silicon layer 708 integrated with an upper cap portion 740 on the buried portion 732. The recessed gates 730 have a bottom surface 734 of the buried portion 732, with the bottom surface 734 being in the top silicon layer 708. The upper portion 740 having substantially straight sidewalls extending from the buried portion 732. The buried portion 732 protrudes laterally in the top surface 714 and longitudinally in and on the top surface 714. The buried portion 732 has a rounded oblong shape with curved edges. The protrusions of the buried portion 732 having curved edges and no straight edges. A top surface 742 of the recessed gates 730 is of the upper portion 740 and is substantially flat.

A first dimension of the recessed gate is a diameter of the buried portion 732 in the second direction. A second dimension of the recessed gate is between the sidewalls of the upper portion 740. In this embodiment, the second dimension is greater than the first dimension.

Furthermore, the cap portion 740 extends in the first direction for a first distance while the buried portion 732 extends in the first direction for a second distance. In this embodiment, the first distance is greater than the second distance. The cap portion 740 is from the top of the gate to the top of the insulating layer 705. The buried portion 732 is from the insulating layer to the bottom surface of the curved recess.

The non-recessed gates 750 are formed on the top silicon layer 708, and unlike the recessed gates 730, are not in the top silicon layer 708. In this embodiment, the non-recessed gates 750 are formed on the fourth insulating layer 709 that is on the top silicon layer 708. Moreover, the non-recessed gates 750 have a square or rectangular shape with a top surface 752 opposite a bottom surface 754. Extending between the top and bottom surfaces 752, 754 are sidewalls 756 of the non-recessed gates 750.

The non-recessed gates 750 extend in the first direction for a third dimension between the top and the bottom surfaces 752, 754. The recessed gates 730 extend in the first direction for a fourth dimension between the top and the bottom surfaces 742, 732. In this embodiment, the third dimension is less than the fourth dimension.

In this embodiment, the top surfaces 742, 752 of the gates 730, 750 are coplanar.

Step 616, not shown in FIGS. 7A-7J for simplicity, includes forming lightly doped drain regions. The lightly doped drain regions are likely formed before the conductive layer is formed.

In FIG. 7I, the remaining nitride layer 771 is removed. Then, at step 618, a plurality of spacers 780 are formed adjacent to the gates 730, 750 and on the SOI substrate. Also not shown in the figures for simplicity, contacts are formed on the SOI substrate, adjacent the gates 730,750, at step 620.

In FIG. 7I, the first nitride layer 771 is removed thereby exposing more surfaces of the first and the fourth insulating layers 705, 709. In particular, the top surface of the first insulating layer 705 is now entirely exposed. In addition, lateral surfaces, and additional top surfaces of the fourth insulating layer 709 are now exposed. The exposed top surfaces of the fourth insulating layer 709 are adjacent and on the buried portion 732 of the recessed gates 730. While the exposed lateral surfaces of the fourth insulating layer 709 are adjacent to the sidewalls 746, 756 of the gates 730, 750.

In embodiments where the first and fourth insulating layers 705, 709 are not present, the top surface 714 of the top silicon layer 708 would be exposed.

At step 618, the plurality of spacers 780 are formed adjacent to the gates 730, 750 in FIG. 7J. Each gate 730, 750 having a set of spacers 780 comprising two spacers 780. Each of the two spacers 780 being adjacent to opposite sidewalls 746, 756 of the gates 730, 750. Moreover, a respective spacer 780 is adjacent to and contacts a sidewall 746, 756. The spacers 780 are formed on the first and the fourth insulating layers 705, 709 that are on the top silicon layer 708. The spacers 780 having edges that taper towards the top silicon layer 708. Tops of the spacers 780 having smaller widths in the second direction than bottoms of the spacers 780. The spacers 780 are spaced from each other.

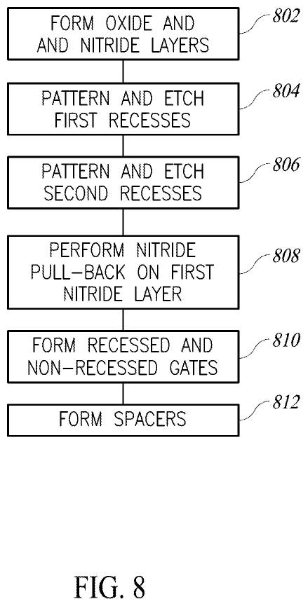

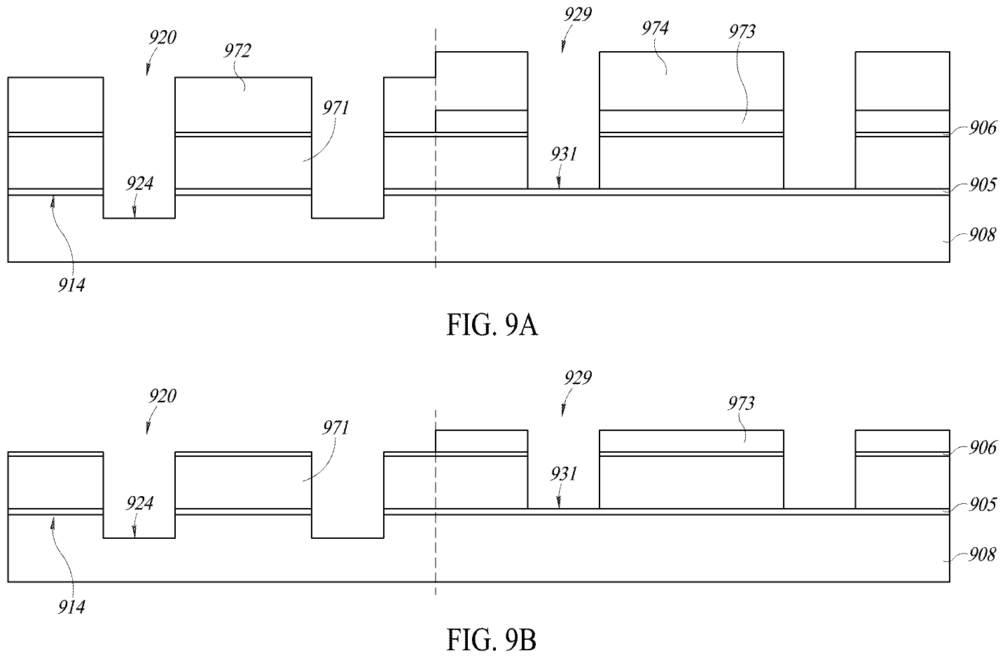

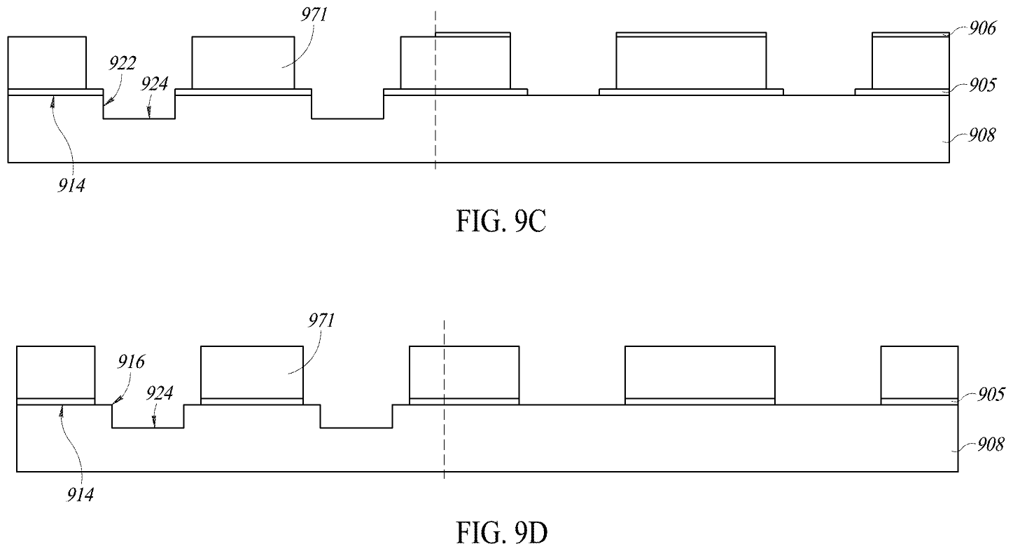

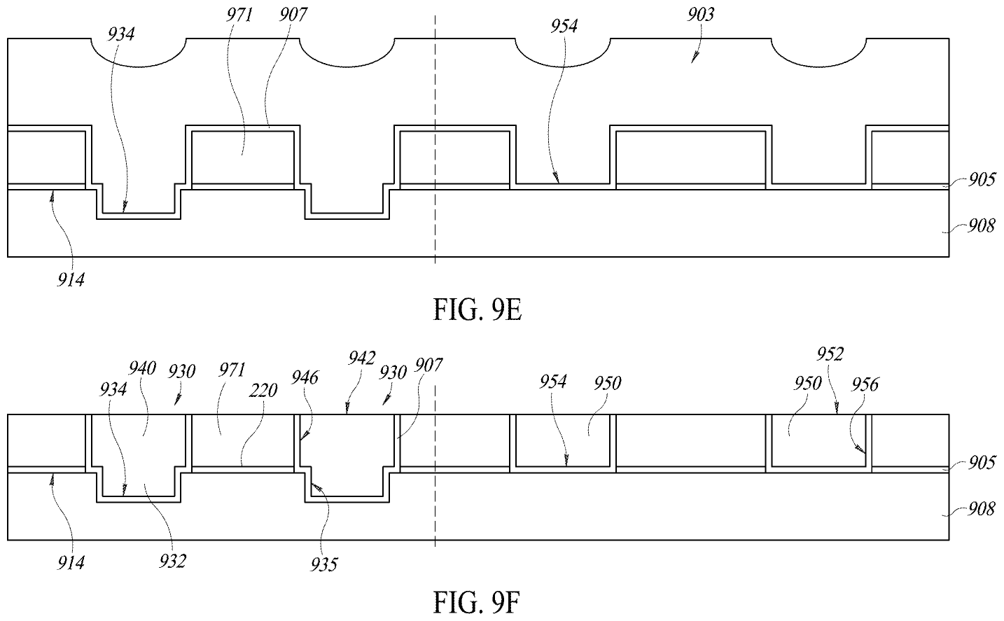

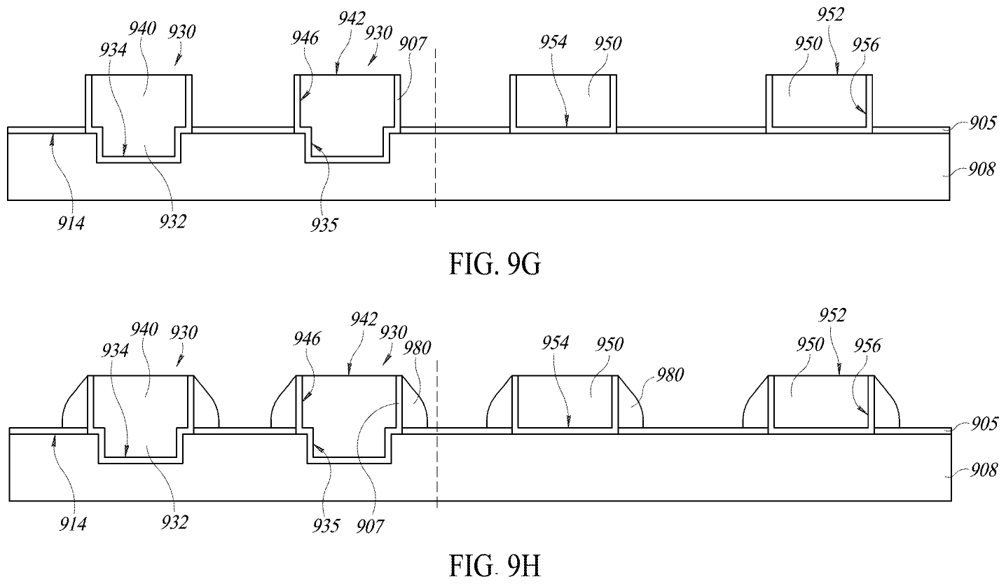

FIG. 8 is a flow chart of steps for a method of manufacturing a plurality of recessed and non-recessed gates 930, 950 according to another embodiment, as detailed in FIGS. 9A-9H. Firstly, in step 802, first and second insulating layer 905, 906 and first and second nitride layers 971, 973 are formed on a top silicon layer 908 of an SOI substrate. Next, in step 804, a first photoresist or resist layer 974 is used to pattern and etch the second nitride layer 973, thereby forming a plurality of first recesses 929. Then, in step 806, a second photoresist or resist layer 972 is used to pattern and etch the first nitride layer 971, thereby forming a plurality of second recesses 920. In step 808, nitride-pull back is performed on the first nitride layer 971, thereby altering the shape of the second recesses 920. Then, in step 810, the plurality of recessed and non-recessed gates 930, 950 are formed, with the recessed gates 930 being in the second recesses 920 and the non-recessed gates 950 being in the first recesses 929. Finally, in step 812, a plurality of spacers 980 are formed adjacent the gates 930, 950.

The SOI substrate includes the top silicon layer 908 on a buried oxide layer. The buried oxide layer being on a bottom silicon layer, both of which are not shown for simplicity. The top silicon layer 908 has a top surface 914, and opposite the top surface 914 is a bottom surface contacting the buried oxide layer.

The top silicon layer 908 may have a thickness of about 60 nm from the bottom surface to the top surface 914. The buried oxide layer may silicon dioxide. In some embodiments, the top silicon layer 908 and the bottom silicon layer may be made of the same material. In other embodiments, the top silicon layer 908 and the bottom silicon layer may be different materials. In this embodiment, the bottom silicon layer is bulk silicon.

At step 802, the first insulating or oxide layer 905 is formed on the SOI substrate. The first insulating layer 905 is continuous on the top surface 914 of the top silicon layer 908. The first insulating layer 905 comprises silicon dioxide or other suitable insulating material. The first insulating layer 905 has a uniform thickness throughout.

Formed on the first insulating layer 905 is the first nitride layer 971 made of silicon nitride or other suitable material. The first nitride layer 971 is continuous and substantially covers a top surface of the first insulating layer 905. The first nitride layer 971 has a uniform thickness throughout.

The second insulating layer 906 is formed on the first nitride layer 971. The second insulating layer 906 is continuous on a top surface of the first nitride layer 971. The second insulating 906 may be made of the same material as the first insulating layer 905, or another suitable insulating material. The second insulating layer 906 has a uniform thickness throughout.

The second nitride layer 973 is formed on a first portion of the second insulating layer 906 and does not entirely cover a top surface of the second insulating layer 906. A second portion of the second insulating layer 906 is not covered by the second nitride layer 973. The second nitride layer 973 may be made of the same material as the first nitride layer 971, or other suitable material. The second nitride layer 973 has a uniform thickness throughout.

At step 804, the first photoresist layer 974 is formed on the second nitride layer 973. Using a mask, the first photoresist layer 974 is used to pattern the second nitride layer 973. The second nitride layer 973 is etched to form the plurality of first recesses 929 in FIG. 9A. Forming the plurality of first recesses 929 includes etching through the first photoresist layer 974, the second insulating layer 906, and the first and the second nitride layers 971, 973. Etching stops at the first insulating layer 905. Forming the plurality of first recesses 929 does not include etching the top silicon layer 908. Each first recess 929 being spaced from each other.

The formed first recesses 929 include bottom surfaces 931 that are delimited by the first insulating layer 905. The bottom surfaces 931 are not in the top silicon layer 908. In embodiments where the first insulating layer 905 is absent, the bottom surfaces 931 are delimited by the top surface 914 of top silicon layer 908.

Etching exposes lateral surfaces of the first and the second nitride layers 971, 973, which delimit sidewalls of the first recesses 929. Lateral surfaces of the second insulating layer 906 are also exposed due to the etching and also delimit sidewalls of the first recesses 929. The exposed lateral surfaces of the first and second nitride layers 971, 973 and the exposed lateral surfaces of the second insulating layer 906 are coplanar.

Due to the etching, the first and the second nitride layers 971, 973 and the first and the second insulating layer 905, 906 are now discontinuous. Instead, the recesses 920, 929 separate portions of the first nitride layer 971 and portions of the second insulating layer 906. The first recesses 929 separate portions of the second nitride layer 973. The second recesses 920 separate portions of the first insulating layer 905.

At step 806, the second photoresist layer 972 is formed on the first nitride layer 971. Using a mask, the second photoresist layer 972 is used to pattern the first nitride layer 971. The first nitride layer 971 is etched to form the plurality of second recesses 920 in FIG. 9A. Forming the plurality of second recesses 920 includes etching through the second photoresist layer 972, the first and the second insulating layers 905, 906, the first nitride layer 971, and a portion of the top silicon layer 908. Etching is carried out in the top surface 914 of the top silicon layer 908 and etching stops in the top silicon layer 908. In particular, etching stops before reaching the center of the top silicon layer 908.

In some embodiments, etching proceeds deeper into the top silicon layer 908. In other embodiments, etching stops nearer the top surface 914 of the top silicon layer 908.

The formed second recesses 920 include bottom surfaces 924 that are delimited by the top silicon layer 908. The second recesses 920 do not extend beyond the top silicon layer 908. Moreover, the second recesses 920 do not extend to reach the buried oxide layer beneath the top silicon layer 908. The bottom surfaces 924 of the second recesses 920 are in the top silicon layer 908.

Sidewalls of the second recesses include portions of the top silicon layer 908. Each second recess 920 being spaced from each other.

Etching exposes lateral surfaces of the first nitride layer 971, which delimit sidewalls of the second recesses 920. Lateral surfaces of the first and the second insulating layers 905, 906 are also exposed due to the etching and also delimit sidewalls of the second recesses 920. The exposed lateral surfaces of the first nitride layer 971, the exposed lateral surfaces of the first and the second insulating layers 905, 906, and the exposed lateral surfaces of the exposed portions of the top silicon layer 908 are coplanar.

In FIG. 9B, the first and the second photoresist layers 974, 972 are removed thereby exposing portions of the second insulating layer 906 and the second nitride layer 973. The top surface of the second insulating layer 906 is exposed where the second nitride layer 973 is not present. In particular, the exposed top surface of the second insulating layer 906 is adjacent to the second recesses 920. The top surface of the second nitride layer 973 is also exposed.

In FIG. 9C, exposed portions of the second insulating layer 906 and the second nitride layer 973 are removed. Unexposed portions of the second insulating layer 906 that were covered the second nitride layer 973 remain. Whereas the exposed portions of the second insulating layer 906 adjacent to the second recesses 920 are removed.

At step 808, in FIG. 9C, nitride pull-back is carried out on the first nitride layer 971. In particular, lateral portions of the first nitride layer 971 are removed that are in the recesses 920, 929. Thereby reducing a width between sidewalls of the first nitride layer 971.

For the second recesses 920, the bottom surfaces 924 are now below or under a larger or wider opening that is between sides of the first nitride layer 971. Between the bottom surfaces 924 and the larger openings are corners that have been formed by the top silicon layer 908 and portions of the first insulating layer 905. In each second recess 920 are two opposite corners. Moreover, the corners protrude towards and face each other in the second recess 920. These corners are absent in the first recesses 929 since they do not include recessed portions of the top silicon layer 908.

Extending from the bottom surfaces 924 of the second recesses to the top surface 914 of the top silicon layer 908 are sidewalls 922 delimited by the top silicon layer 908. The sidewalls 922 are below or under the larger upper opening of the second recess 920. Between the sidewalls 922 is a first dimension and between the sides of the first nitride layer 971 in the second recess 920 is a second dimension. The first dimension is less than the second dimension.

In other embodiments, the first and the second dimensions are substantially similar. In other embodiments, the first dimension is greater than the second dimension.

The top surface of portions of the first insulating layer 905 are now exposed. The exposed portions of the first insulating layer 905 are no longer covered by the first nitride layer 971. The exposed portions of the first insulating layer 908 extend outward into the first and the second recesses 929, 920.

The second insulating layer 906 on the first nitride layer 971 is now exposed. In particular, the top surface of the second insulating layer 906 is exposed.

Then, in FIG. 9D, the second insulating layer 906 and the exposed portions of the first insulating layer 905 in the recesses 929, 920 are removed. Lateral surfaces of the first nitride layer 971 being coplanar with lateral surfaces of the first insulating layer 905.

Portions of the top surface 914 of the top silicon layer 908 are no longer covered by the first insulating layer 905, thereby exposing portions of the top surface 914 in the second recesses 920. Top surfaces of the corners 916 in the second recesses 920 are now exposed with the corners 916 being between the exposed top surface 914 and the sidewalls 922.

The first recesses 929 have a square or rectangular shape. The top surface 914 of the second silicon layer 908 delimits the bottoms of the second recesses 929. The bottom surfaces 931 of the second recess 929 being the top surface 914 of the top silicon layer 908.

Then, a third insulating layer 907 is formed on the SOI substrate in FIG. 9E. The third insulating layer 907 being on the first nitride layer 971 and top silicon layer 908. In particular, the third insulating layer 907 covers the exposed regions of the top silicon layer 908, including in the recesses 920, 929. Bottom surfaces 924, 931 of the recesses 920, 929 are covered by the third insulating layer 907. In the second recesses 920, the sidewalls 922 and corners 916 are also covered by the third insulating layer 907. In the first recesses 929, lateral surfaces of the first nitride layer 971 are coated with the third insulating layer 907. Top surfaces of the first nitride layer 971 are covered by the third insulating layer 907.

The third insulating layer 907 has a uniform thickness throughout. The third insulating layer 907 is continuous over the first nitride layer 971 and top silicon layer 908.

Lateral surfaces of the first insulating layer 905 contact the third insulating layer 907. The first insulating layer 905 being integral with the third insulating layer 907.

The third insulating layer 907 may be of the same material as the first or second insulating layers 905, 906, or other suitable material. In other embodiments, the third insulating layer 907 is absent.

Then, gate polysilicon material 903 is deposited on the SOI substrate. The gate polysilicon material 903 filling the recesses 920, 929 and being on the third insulating layer 907. The recesses 920, 929 are entirely filled with the gate polysilicon material 903, including covering the bottom surfaces 924, 931. The gate polysilicon material 903 forms bottom surfaces 954 of the non-recessed gates 950 and bottom surfaces 934 of the recessed gates 930.

Moreover, the gate polysilicon material 903 overfills the recesses 920, 929 and contacts the third insulating layer 971 that is on the first nitride layer 971.

In other embodiments, the gate polysilicon material 903 partially fills the recesses 920, 929.

In other embodiments, the gate polysilicon material 903 does not overfill the recesses 920, 929 and does not contact the third insulating layer 971 that is on the first nitride layer 971.

At step 810, the plurality of recessed and non-recessed gates 930, 950 are formed. In FIG. 9F, chemical mechanical polishing (CMP) is carried out to remove excess portions of the gate polysilicon material 903, thereby defining the gates 930, 950.

In other embodiments, forming the gates 930, 950 includes removing the excess gate polysilicon material 903 via suitable methods other than CMP.

Portions of the third insulating layer 907 are also removed. The removed portions of the third insulating layer 907 include portions on the first nitride layer 971. In some embodiments, removed portions of the third insulating layer 907 include portions adjacent to the recesses 920, 929.

In some embodiments, portions of the first nitride layer 971 are removed. Removed portions of the first nitride layer 971 include the top surface.

Top surfaces 942 of the recessed gates 930 are coplanar with top surfaces 952 of the non-recessed gates 950. The top surfaces 942 of the recessed gates 930 being of the upper portions 940. The gates 930, 950 being separated by the first nitride layer 971. The exposed top surfaces of the first nitride layer 971 are coplanar with the top surfaces 942, 952 of the gates 930, 950.

Portions of the third insulating layer 907 being between the gates 930, 950 and the first nitride layer 971. Exposed top surfaces of the third insulating layer 907 are coplanar with the top surfaces 942, 952 of the gates 930, 950.

The recessed gates 930 are formed in the second recesses 920, with each recessed gate 930 being in a respective recess 920. The recessed gates 930 being adjacent and spaced from each other.

The non-recessed gates 950 are formed in the first recesses 929. The non-recessed gates 950 being adjacent and spaced from each other.

In other embodiments, only one or at least one recessed gate 930 is formed. In other embodiments, only one or at least one non-recessed gate 950 is formed. In other embodiments, non-recessed gates 950 are not formed.

Then, in FIG. 9G, the first nitride layer 971 is removed. Lateral surfaces of the third insulating layer 907 are exposed. Top surfaces of the first insulating layer 905 are also exposed.

In other embodiments, the top surface 914 of the top silicon layer 908 is exposed instead of the first layer 905. In some embodiments, lateral surfaces of the gates 930, 950 are exposed instead of the third insulating layer 907.

At step 812, the plurality of spacers 980 are formed adjacent the gates 930, 950 in FIG. 9H. The spacers 980 are formed on the first insulating layer 905 and contact the third insulating layer 907.

In other embodiments, where the first insulating layer 905 is not present, the spacers 980 are formed on the top silicon layer 908.

FIG. 9H is the device 900 according to one embodiment.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising:
a silicon-on-insulator (SOI) substrate including:
first and second silicon layers, the first silicon layer having a first surface;
a first insulating layer between the first silicon layer and the second silicon layer; and
a recess in the first surface of the first silicon layer;
a second insulating layer on the first surface of the first silicon layer and in the recess; and
a first gate on the second insulating layer, the first gate having a first gate portion in the recess and a second gate portion on the first gate portion, the second gate portion being a different dimension than the first gate portion in a first direction.

2. The device of claim 1, wherein the recess includes sidewalls extending from the first surface of the first silicon layer to a second surface in the recess, the second insulating layer being on the sidewalls and the second surface in the recess.

3. The device of claim 2, wherein the first gate portion has a first dimension between the sidewalls of the recess, and the second gate portion has a second dimension between a first edge and a second edge, the first dimension being less than the second dimension.

4. The device of claim 2, wherein the first gate portion has a first dimension between the sidewalls of the recess, and the second gate portion has a second dimension between a first edge and a second edge, the first dimension and the second dimension are substantially equal.

5. The device of claim 1, wherein the recess is curved from a first side to an opposite second side.

6. The device of claim 5, wherein the first gate portion has a first dimension between the first side and the second side, and the second gate portion has a second dimension between a first side and a second side, the first dimension being greater than the second dimension.

7. The device of claim 6, the first gate portion extends past the first surface of the first silicon layer.

8. The device of claim 7, wherein the second insulating layer is between the first silicon layer and the first gate portion that extends past the first surface of the first silicon layer.

9. A method, comprising:
forming a recess in a first surface of a first silicon layer of a silicon-on-insulator (SOI) substrate, the SOI substrate including a first insulating layer and a second silicon layer, the first insulating layer between the first silicon layer and the second silicon layer;
forming a second insulating layer on the first surface of the first silicon layer and in the recess; and
forming a first gate on the second insulating layer, the first gate having a first gate portion in the recess and a second gate portion having a first end on the first gate portion, the second gate portion having a second end opposite a third end, the third end being transverse to the first end.

10. The method of claim 9, comprising:
forming a third insulating layer on the first silicon layer; and
forming a first nitride layer on the first surface of the first silicon layer, wherein forming the recess includes etching through the first nitride layer and the third insulating layer.

11. The method of claim 10, comprising, after forming the second insulating layer and before forming the first gate:
forming a second nitride layer on the first nitride layer; and
removing the first and second nitride layers.

12. The method of claim 10, comprising, after forming the recess and before forming the second insulating layer, removing portions of the first nitride layer via nitride pull-back.

13. The method of claim 12, wherein forming the first gate includes:
forming a first conductive layer on the second insulating layer; and
removing portions of the first conductive layer and the second insulating layer via chemical mechanical polishing (CMP), wherein the portions of the second insulating layer are on the first nitride layer.

14. The method of claim 13, wherein, after removing portions of the first conductive layer and the second insulating layer, a surface of the first gate is coplanar with a surface of the first nitride layer, the first surface of the first gate being opposite the recess, and the first surface of the first nitride layer being opposite the first surface of the first silicon layer.

15. The method of claim 14, wherein the first gate portion has a first dimension between sidewalls of the recess, the second gate portion has a second dimension between the second end and the third end, and the first dimension of the first gate portion is less than the second dimension of the second gate portion.

16. The method of claim 9, wherein forming the recess includes:
forming a third insulating layer on the first surface of the first silicon layer having a nitride layer, wherein forming the third insulating layer includes growing the third insulating layer in the recess; and
removing the third insulating layer, the recess being curved from a first end to an opposite second end, the first and second ends extending to the first surface of the first silicon layer, the nitride layer extending over portions of the recess.

17. The method of claim 16, wherein forming the second insulating layer includes forming on the nitride layer.

18. A device, comprising:
a substrate having a surface, the substrate including:
a first silicon layer, the surface is of the first silicon layer;
a buried oxide layer;
a second silicon layer, the buried oxide layer is on the second silicon layer and the first silicon layer is on the buried oxide layer, the substrate is a silicon-on-insulator (SOI) substrate; and
a curved recess in the surface;
a recessed gate having a curved portion in the curved recess and a central portion on the curved portion, the curved portion extending in a first direction to the central portion; and
a first oxide layer between the recessed gate and the substrate, the first oxide layer extending on the surface of the substrate and in the curved recess.

19. The device of claim 18, wherein the central portion of the recessed gate has a first dimension in the first direction, the curved portion has a second dimension in the first direction, the second dimension is less than the first dimension.

20. The device of claim 19, wherein the central portion of the recessed gate has a third dimension in a second direction transverse the first direction, the curved portion has a fourth dimension in the second direction, the fourth dimension is greater than the third dimension.

21. The device of claim 18, wherein the curved portion of the recessed gate has a convex surface in the substrate.
